(19) United States
(12) Patent Application Publication
(10) Pub. No.: US 2007/0051315 A1
(43) Pub. Date: Mar. 8, 2007

(54) Apparatus and method for producing nano-powder

(75) Inventor: Ga-Lane Chen, Fremont, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/403,214

(22) Filed: Apr. 12, 2006

(30) Foreign Application Priority Data
Sep. 5, 2005 (CN) 200510037128.6

(51) Int. Cl. C23C 16/00; B29B 9/00

(52) U.S. Cl. 118/723 EB; 264/5; 977/906

(57) ABSTRACT

An apparatus for producing nano-powder includes a laser generator for generating laser beams, a reaction chamber having an incident window configured for allowing the beams to pass therethrough, a vacuum system for evacuating the reaction chamber, a reactive gas input device for introducing reactive gases into the reaction chamber, a microwave unit for introducing microwave into the reaction chamber and creating microwave electron cyclotron resonance in the reaction chamber, and a powder collector for collecting nano-powder.

### BACKGROUND

1. Technical Field

The present invention relates to nanomaterials, and more particularly to an apparatus and a method for producing nano-powder.

2. Description of Related Art

Compared to other materials, nanomaterials have many unusual properties, such as low melting point, low-density, good toughness, good dielectric properties, acoustic properties, and optical stability They are widely used in a variety of diverse fields, such as in catalytic processes, cements, ceramics, carbon fiber materials, and in photo-electronic and microelectronic devices.

Today many researchers are becoming increasingly involved in the ongoing development of methods for producing the nanomaterials. The most common methods for producing nanomaterials include vapor phase methods, liquid phase methods, and solid phase methods.

Perfect nano-powder should have the following characteristics: small particle size, no agglomeration amongst the particles, narrow particle size distribution, approximate spherical shape, and high purity However, the nano-powder produced by the above mentioned methods does not meet these demands.

Laser induced chemical vapor deposition (LICVD) method has developed rapidly since Haggerty developed it in 1980's. The nanomaterials produced by the LICVD method meet the perfect nano-powder better than that produced in the vapor methods, liquid phase methods, or in the solid phase methods.

The principle of the LICVD method is that reactive gases absorb large amounts of laser light at particular wavelengths, thus inducing reactive gases laser heat absorbance and promoting reactivity Thus the nano-powder is produced during a chemical reaction within the reactive gases. Because the power of the laser is limited, the laser cannot induce the reactive gases heat absorbance adequately When the reactive gases do not react adequately with each other low usage of the reactive gases and low production rate of nano-powder results.

What is needed, therefore, is an apparatus and a method for producing nano-powder that can increase the usage of the reactive gases and the rate at which nano-powder is produced.

### SUMMARY

In a preferred embodiment, an apparatus for producing nano-powder includes a laser generator for generating laser beams, a reaction chamber having an incident window configured for allowing the beams to pass therethrough, a vacuum system for evacuating the reaction chamber, a reactive gas input device for introducing reactive gases into the reaction chamber, a microwave unit for introducing microwave radiation into the reaction chamber thus creating microwave electron cyclotron resonance in the reaction chamber, and a powder collector for collecting nano-powder.

In another preferred embodiment, a method for producing nano-powder comprises the steps of: providing a reaction chamber; evacuating the reaction chamber using a vacuum system; irradiating an interior of reaction chamber with laser beams; introducing a microwave into the reaction chamber and creating microwave electron cyclotron resonance in the reaction chamber; introducing reactive gases into the reaction chamber, thereby obtaining nano-powder by means of the laser irradiation and the microwave electron cyclotron resonance; collecting the nano-powder by means of a powder collector.

Other advantages and novel features will become more apparent from the following detailed description of present apparatus and method for producing nano-powder, when taken in conjunction with the accompanying drawings.

### BRIEF DESCRIPTION OF THE DRAWINGS

Many aspects of the apparatus and method for producing nano-powder can be better understood with reference to the following drawings. The components in the drawings are not necessarily drawn to scale, the emphasis instead being placed upon clearly illustrating the principles of the present invention. Moreover, in the drawings, like reference numerals designate corresponding parts throughout the several views.

FIG. 1 is a schematic, plan view of an apparatus for producing nano-powder in accordance with a preferred embodiment;

FIG. 2 is a schematic, cutaway view of a reactive gas input device of the apparatus of FIG. 1; and

FIG. 3 is a schematic, plan view of a vacuum system of the apparatus of FIG. 1.

### DETAILED DESCRIPTION OF PREFERRED EMBODIMENT

Reference will now be made to the drawing figures to describe the preferred embodiment of the present apparatus and method for producing nano-powder in detail.

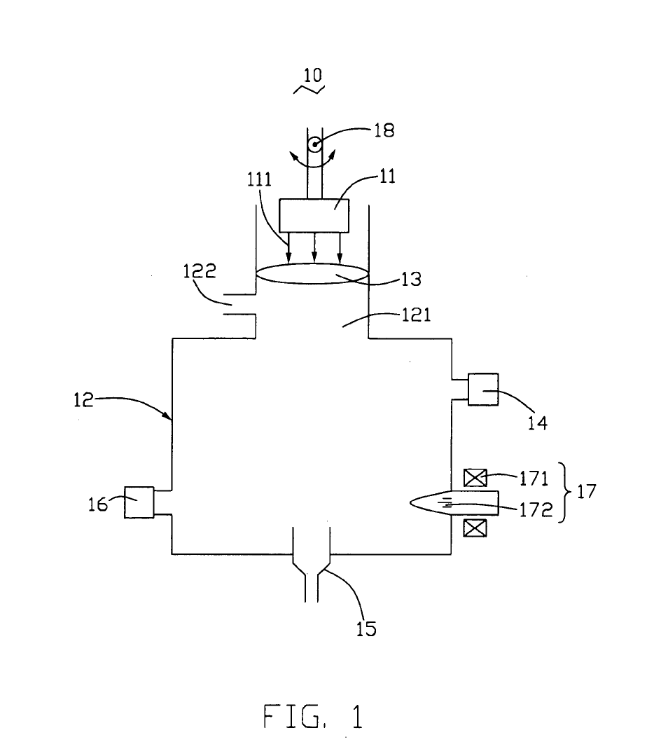

Referring to FIG. 1, an apparatus 10 for producing nano-powder is shown. The apparatus 10 includes a laser generator 11, a reaction chamber 12, an optical system 13, a reactive gas input device 14, a powder collector 15, a vacuum system 16, and a microwave unit 17.

The laser generator 11 is for example generally a continuous wave carbon dioxide (CO₂) laser generator. The laser generator 11 is rotatable about a pivot point 18 such that more regions inside the reaction chamber 12 can be irradiated by the laser beams emitted therefrom. The laser generator 11 generates parallel laser beams 111. A power of the laser beams 111 is in the range from about 100 watts to about 1200 watts.

The reaction chamber 12 is a closed container and generally made of stainless steel. An incident window 121 is located on the reaction chamber 12 facing towards the laser generator 11.

The optical system 13 is located between the incident window 121 and the laser generator 11 and can also be rotatable jointly with the laser generator 11 about the pivot point 18. The optical system 13 includes a focusing lens made of ZnAs (Zinc Arsenide). The function of the optical system 13 is to focus the laser beams 111, so that the energy of the laser beams 111 can irradiate with a concentrated area. Then the focused laser beams 111 pass through the incident window 121 and irradiate the reaction chamber 12.

In order to avoid damage to the optical system 13 caused by pollution of reactive gases or nano-powder produced, a protection device is positioned between the incident window 121 and the optical system 13. The laser beams 111 focused by the optical system 13 pass through the protection device and then irradiate the reaction chamber 12. The protection device can be a first protection input device 122. A flow of a first protection gas inputted by the first protection gas input device 122 can take away the reactive gases or nano-powder, so the protection gas can protect the optical system 13. The first protection gas is generally argon gas, hydrogen gas, or helium gas. In addition, the protection device can also be a transparent glass plate.

The reactive gas input device 14 is located near the incident window 121. The reactive gas input device 14 introduces the reactive gases into the reaction chamber 12. Referring to FIG. 2, the reactive gas input device 14 includes a gas source 141, a gas guide pipe 142, a flow rate controller 143, and a gas nozzle 144 connected in series in that order. The gas source 141 introduces the reactive gases, which flow to the flow rate controller 143 through the gas guide pipe 142. The flow rate controller 143 keeps the reactive gas flow at a predetermined flow rate. Thus the reactive gases go into the reaction chamber 12 through the gas nozzle 144. The flow rate controller 143 can be either a flowmeter or a kinemometer. The gas nozzle 144 is a hollow circular cone. In addition, according to types of the reactive gases in the practical requirement, a plurality of reactive gas input devices 14 are connected to the reaction chamber 12. Each reactive gas input device 14 is used to input one type of reactive gas.

For adjusting pressure inside the reaction chamber 12, a second protection gas input device 145 is disposed between the gas nozzle 144 and the flow rate controller 143. When the reactive gases are introduced, a second protection gas is inputted through the second protection gas input device 145. The second protection gas is argon gas. The second protection gas is used to limit the flow of the reactive gases, compress the reaction area, transmit and cool the resultant product. The second protection gas input device 145 is positioned between the gas source 141 and the flow rate controller 143. In addition, the second protection gas can be mixed into the reactive gases and introduced together with the reactive gases into the reaction chamber 12 instead of designing the second protection gas input device 145.

The powder collector 15 is located on an opposite side of reaction chamber 12 to the laser generator 11. The powder collector 15 can move up and down. The reactive gases react with each other in the reaction chamber 12 and thereby produce nano-powder. The powder collector 15 separates the produced nano-powder from the reactive gases and collects the nano-powder. Thus the powder collector 15 outputs nano-powder from the reaction chamber 12. The powder collector 15 can be a funnel.

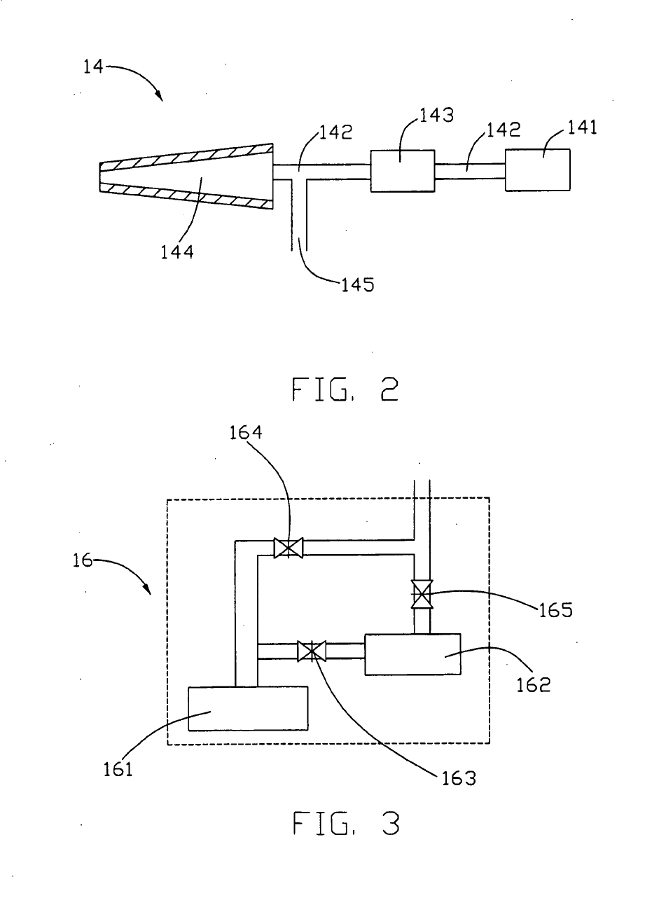

Referring to FIG. 3, the vacuum system 16 includes a mechanical pump 161, a turbo pump 162, a first valve 163, a second valve 164, and a third valve 165. The first valve 163 connects the mechanical pump 161 and the turbo pump 162. The mechanical pump 161 joins with the reaction chamber 12 through the second valve 164. The turbo pump 162 connects with the reaction chamber 12 by the third valve 165. The function of the vacuum system 16 is to vacuum the reaction chamber 12.

The microwave unit 17 includes a coil 171 and an antenna 172. The coil 171 can provide a magnetic field. The antenna 172 can introduce the microwave into the reaction chamber 12. The microwave unit 17 can generate microwaves with frequency of n×2.45 gigahertz. A numeral of n is an integer either equal to or greater than 1. The antenna 172 is a quarter wavelength antenna.

The microwave generates an electromagnetic field in the reaction chamber 12. When the frequency of the electron cyclotron of the electromagnetic field is equal to the frequency of the microwave, a microwave electron cyclotron resonance phenomenon is generated. The electrons in the electromagnetic field absorb power from the microwaves and generate high power electrons. The high power electrons ionize the reactive gases generating highly reactive plasma. The plasma reacts and generates the nano-powder.

On one hand, the apparatus 10 uses the laser beams 111 to induce the reactive gases laser heat absorbance and promote reactivity, and produce nano-powder in a chemical reaction of the reactive gases. On the other hand, the apparatus 10 uses the microwave electron cyclotron resonance to make the reactive gases ionize and the reactive gases generate the plasma. The plasma of reactive gases reacts with each other. The nano-powder then cools and stops growing. Then the powder collector 15 collects the nano-powder. Under the combined action of the laser beams 111 and the microwave electron cyclotron resonance, the reaction of the reactive gases is greatly improved

A method for producing nano-powder, for example silicon nitride (Si₃N₄), using the apparatus 10 is described in detail below.

Firstly, the reaction chamber 12 is evacuated by the vacuum system 16. The process is described below. The first valve 163 and the third valve 165 are closed and the second valve 164 is opened. The vacuum system 16 is pumped down by the mechanical pump 161. After the pressure in the reaction chamber 12 reaches a predetermined numerical value, such as 2×10⁻³ torr, the second valve 164 is closed and the third valve 165 is opened. The reaction chamber 12 is then pumped both by the mechanical pump 161 and by the turbo pump 162. Thus the pressure of the reaction chamber 12 reaches the reaction pressure, such as 2×10⁻⁶ torr, and preferably 2×10⁻⁷ torr.

Secondly, the laser generator 11 and microwave unit 17 are turned on. While the reactive gases silicon hydrogen (SiH₄) and ammonia (NH₃) are introduced into the reaction chamber 12 through the reactive gas input device 14, the flow rate controller 143 keeps the flow rate of NH₃ and SiH₄ at a predetermined flow rate. Under action of the laser beams 111, portions of the reactive gases NH₃ and SiH₄ undergo laser heat absorbance and nano-powder Si₃N₄ is produced, according to the following chemical equation:
3SiH₄+4NH₃=Si₃N₄+12H₂

Under action of the microwave electron cyclotron resonance, portions of the reactive gases NH₃ and SiH₄ generate highly reactive plasma and nano-powder Si₃N₄ is produced within the plasma, according to the above chemical equation.

After a time period according to the practical requirement, the reactive gases stop being introduced and the laser generator 11 and the microwave unit 17 are turned off The powder collector 15 then collects the nano-powder.

Although the present invention has been described with reference to specific embodiments, it should be noted that the described embodiments are not necessarily exclusive, and that various changes and modifications may be made to the described embodiments without departing from the scope of the invention as defined by the appended claims.

What is claimed is:

1. An apparatus for producing nano-powder, comprising:
a laser generator for generating laser beams;
a reaction chamber having an incident window configured for allowing the laser beams to pass therethrough;
a vacuum system for evacuating the reaction chamber;
a reactive gas input device for introducing reactive gases into the reaction chamber;
a microwave unit for introducing a microwave radiation into the reaction chamber and creating microwave electron cyclotron resonance in the reaction chamber; and
a powder collector for collecting the nano-powder.

2. The apparatus as claimed in claim 1, wherein the microwave unit comprises a coil configured for providing a magnetic field and an antenna configured for introducing the microwave into the reaction chamber.

3. The apparatus as claimed in claim 2, wherein the antenna is a quarter wavelength antenna.

4. The apparatus as claimed in claim 1, wherein a frequency of the microwave is n×2.45 gigahertz, n is an integer equal to and greater than 1.

5. The apparatus as claimed in claim 1, wherein the laser generator is a carbon dioxide laser generator.

6. The apparatus as claimed in claim 5, wherein a power of the carbon dioxide laser is in the range from 100 watts to 1200 watts.

7. The apparatus as claimed in claim 1, wherein the laser generator is rotatable.

8. The apparatus as claimed in claim 1, further comprising an optical system configured for converging the laser beams from the laser generator, and a protection device disposed between the optical system and the incident window for protecting the optical system.

9. The apparatus as claimed in claim 8, wherein the protection device is a first protection gas input device for providing a first protection gas arranged between the optical system and incident window.

10. The apparatus as claimed in claim 7, wherein the optical system is rotatable.

11. The apparatus as claimed in claim 9, wherein the first protection gas is argon gas, hydrogen gas, or helium gas.

12. The apparatus as claimed in claim 8, wherein the protection device is a transparent glass plate disposed between the optical system and incident window.

13. The apparatus as claimed in claim 1, wherein the reactive gas input device comprises a gas source, a gas guide pipe, a flow rate controller, and a nozzle connected in series in that order.

14. The apparatus as claimed in claim 13, wherein the reactive gas input device further comprises a second protection gas input device interconnected between the flow rate controller and the nozzle for introducing a second protection gas.

15. The apparatus as claimed in claim 14, wherein the second protection gas is argon gas.

16. The apparatus as claimed in claim 1, wherein the vacuum system includes a mechanical pump, a turbo pump, a first valve connecting the mechanical pump and the turbo pump, a second valve connecting the mechanical pump and the reaction chamber, and a third valve connecting the turbo pump and the reaction chamber.

17. The apparatus as claimed in claim 1, wherein the optical system comprises a lens disposed between the incident window and the laser generator.

18. The apparatus as claimed in claim 1, wherein the powder collector is a funnel.

19. A method for producing nano-powder, comprising the steps of:
providing a reaction chamber;
evacuating the reaction chamber using a vacuum system;
applying a laser irradiation to an interior of the reaction chamber;
introducing a microwave into the reaction chamber and creating a microwave electron cyclotron resonance in the reaction chamber;
introducing reactive gases into the reaction chamber, thereby obtaining nano-powder produced by means of the laser irradiation and the microwave electron cyclotron resonance; and
collecting the nano-powder by means of a powder collector.
